(19) United States
(12) Patent Application Publication
(10) Pub. No.: US 2009/0302135 A1
(43) Pub. Date: Dec. 10, 2009

(54) Protective Encapsulation

(76) Inventors: Joachim R. Kiefer, Losheim am See (DE); Christpher Andrew Goat, Kent (GB)

Correspondence Address: DELPHI TECHNOLOGIES, INC., M/C 480-410-202, PO BOX 5052, TROY, MI, 48007, US

(21) Appl. No.: 12/226,750

(22) PCT Filed: Apr. 24, 2007
(86) PCT No.: PCT/GB2007/001490

§ 371 Date: Feb. 18, 2009

(30) Foreign Application Priority Data
Apr. 25, 2006 (EP) 06252206.5

(51) Int. Cl. F02M 51/00; H01L 41/22; H01L 41/053

(52) U.S. Cl. 239/569; 29/25.35; 310/340

(57) ABSTRACT

An electrical device such as a piezoelectric actuator is protected against permeation by injurious fluids such as fuel (diesel/gasoline) and water by encapsulating the device with a shape memory metallic material. The shape memory metallic material may be in the form of a tube manufactured to the required dimensions for encapsulation of the device. The tube may then be plastically deformed, such as by stretching, before being placed over the device and heated above its transformation temperature to recover its original shape. The invention is particularly suitable for protecting passivated piezoelectric actuators.

### TECHNICAL FIELD

This invention relates to methods of encapsulation to protect against permeation by fluids, such as fuel and chemicals and/or water, and more particularly, but not exclusively, to the protection of piezoelectric actuators, for example, in fuel injectors of internal combustion engines. The invention also relates to a piezoelectric actuator protected by encapsulation.

### BACKGROUND OF THE INVENTION

Known piezoelectric fuel injectors typically employ piezoelectric actuators made from a stack of piezoelectric ceramic discs or plates, each being connected to an electrode for electrically charging and discharging. The actuator is typically arranged for mechanically opening and closing an injector valve that includes a valve needle arranged to meter fuel as it is injected into the engine. Such piezoelectric actuators may be located in a chamber containing fuel, at fuel injection pressure, and may be configured to control movement of the valve needle through a mechanical and/or hydraulic coupling. An example of a conventional piezoelectric fuel injector is disclosed in the applicants' U.S. Pat. No. 6,520,423, which utilizes a hydraulic coupling to lift the valve needle off the valve seat so as to enable opening of the injector in response to longitudinal expansion of the piezoelectric actuator.

Piezoelectric ceramic multi-layers are known in many configurations. One common configuration aims to maximize longitudinal strain, i.e., longitudinal movement, by including a maximized, piezoelectrically-active cross-section. To achieve this, the internal electrodes, of both polarities, are exposed on two faces of the piezoelectric element. The high electrical field applied to the element so as to achieve high strain, however, induces a risk of shorting between the internal electrodes of opposing polarities. To prevent surface breakdown associated with such shorting, the exposed electrode faces of the piezoelectric, multilayer element are preferably covered with a passivation material, usually of silicone rubber.

Passivation of the piezoelectric element potentially provides a long-term barrier to surface shorting while it remains in a dry and fuel free environment. When exposed to fuel and/or moisture, however, the passivation material may lose its dielectric strength, leading to failure in that it may no longer be able to fulfil its intended purpose. It is therefore highly desirable that a barrier be applied over the piezoelectric element and passivation layer so as to prevent infiltration of fuel and water.

The applicants have experimented with a number of methods of encapsulating piezoelectric stacks covered with a passivation material, attempting to reduce the permeation of fuel and/or water. One method currently being investigated by the applicants to achieve this function is the use of a polymeric heat shrink material comprising a fluoropolymer. Alternatively, it has been proposed to overmould the piezoelectric actuator with a thermoplastic polymer.

In a further method, it has been proposed to use a metal tube around the piezoelectric actuator. While this concept would provide a barrier to fuel and moisture, it is difficult to provide adequate end sealing and to ensure that no unfilled space is left between the passivation material and the metal tube.

Against this background, the main object of the present invention is to provide an alternative method of encapsulation that, when applied to a piezoelectric actuator, greatly reduces fuel (diesel/gasoline) and water permeation and thus improves the lifetime of piezoelectrically driven injectors.

### SUMMARY OF THE INVENTION

To this end, and in one aspect, the present invention resides in a method of protecting an electrical device, such as a piezoelectric actuator, against permeation by injurious fluids such as fuel (diesel/gasoline) and water, the method including encapsulating the electrical device with a shape-memory, metallic material.

In another aspect, the present invention resides in the use of a shape-memory, metallic material so as to encapsulate an electrical device, such as a piezoelectric actuator, and so as to protect against permeation by injurious fluids such as fuel (diesel/gasoline) and water.

In an exemplary embodiment, the invention also resides in an electrical device, such as a piezoelectric actuator encapsulated by a shape-memory, metallic material so as to protect against permeation by injurious fluids such as fuel (diesel/gasoline) and water.

In a further aspect, the present invention resides in a fuel injector incorporating a piezoelectric actuator encapsulated by a shape-memory, metallic material so as to protect against permeation by injurious fluids such as fuel (diesel/gasoline) and water.

By means of the shape-memory, metallic material encapsulation of this invention, which material acts as a fuel/moisture barrier, permeation by fuel (diesel/gasoline) and water is greatly reduced, and the lifetime of piezoelectric-driven injectors is increased.

Moreover, in comparison to the above-presented prior art proposals, the invention provides the advantage that permeation by fuel and water is effectively prevented due to the metallic nature of the shape memory material and the bulk thickness of the encapsulation material. Furthermore, the use of a shape-memory, metallic material in accordance with the invention permits a greater freedom with regard to size, and thus sealing, options.

The shape-memory, metallic material can be any appropriate metallic material consistent with achieving a suitable reduction in permeation by diesel or gasoline fuel and water and is preferably a shape-memory alloy.

For example, the shape-memory alloy may be a nickel titanium alloy, such as that manufactured by Johnson Matthey under the trade name NITINOL (Nickel Titanium Naval Ordnance Laboratory). Alloying additions such as iron may be included in order to modify the transformation temperature of the shape-memory alloy. Other shape-memory alloys based on copper may be used, but nickel titanium alloys are preferred for their super-elastic shape-memory characteristics.

In an exemplary embodiment, shape-memory, metallic encapsulation materials of this invention provide an impermeable barrier to diesel/gasoline fuels and water and can be used as encapsulation materials for piezoelectric actuators for direct injection engines of diesel as well as gasoline fuel types.

In an exemplary embodiment, a shape-memory, metallic material is in the form of a tube that is manufactured prior to the encapsulation process. For example, the tube may be produced mainly by machining to final dimensions with a tolerance of less than 50 microns, so as to form an original shape-memory, metallic tube that can be used to encapsulate a piezoelectric stack. Advantageously, the machined, shape-memory, metallic tube has a wall thickness of less than one millimetre, and preferably between about 200 to 500 microns.

Subsequently, the original shape-memory, metallic tube is plastically deformed below its transformation temperature, for example, by inserting a mandrel into the tube so as to stretch the tube such that the inner tube surface area becomes larger than the actual surface area of the piezoelectric stack, thus allowing the tube to be placed over, and cover, the stack and anywhere else necessary to isolate the passivation material. Stretching the tube by about 4% from its original shape will usually be sufficient to permit insertion of the stack.

Then, by heating the deformed shape memory metallic tube, on the piezoelectric stack, above its transformation temperature, for example, to approximately 220° C., the tube recovers its original shape. After heating, the metallic tube fits to the dimensions of the passivated piezoelectric stack and preferably also its end pieces, effectively hermetically sealing the tube on to the end pieces.

In a preferred embodiment, the size of the tube is selected so that the stress on the actuator parts is very small, except in the region of the end pieces where it is necessary to ensure effective sealing. For example, the tube may be machined to allow a very thin gap, say in the region of 0.05 mm or less, between the tube (after recovery to its original shape) and the passivation material covering the outer actuator surface.

Alternatively, or in addition thereto, the low stress state on the passivation material may be achieved through the precise composition of the shape memory material and its transformation temperature. Generally, the transformation temperature is a function of the alloy type, composition and also of the thermomechanical treatments applied.

It is preferred that the transformation temperature be such that the shape memory material remains in its austenitic state under the typical operating temperatures encountered by the actuator within the fuel injector. In this regard, the shape memory alloy transformation temperature is preferably outside the range of −40° C. to 150° C.

Rather than the shape memory alloy transformation temperature being above the upper operating temperature range, an alternative is to ensure the transformation temperature is below the lowest operating temperature, so that the shape memory alloy remains in its austenitic state during service.

For improving sealing around the ends of the piezoelectric stack, an adhesive or elastomeric layer may be used between the sealing surfaces of the end pieces and the shape memory metallic tube. This additional sealant phase may, for example, be applied on the surface of the end pieces or in channels around the sealing surface.

In order that the invention may be more readily understood, some embodiments in accordance therewith will now be described, by way of example, with reference to the accompanying drawings.

### BRIEF DESCRIPTION OF THE DRAWINGS

FIG. 1 is a cross-sectional view of a piezoelectric actuated fuel injector like that disclosed in U.S. Pat. No. 6,520,423 and includes a piezoelectric actuator comprising a stack of piezoelectric elements;

FIG. 2 shows, schematically, a multilayer piezoelectric element before and after passivation; and

FIG. 3 shows, schematically, a succession of steps in a method of producing a protective encapsulation of a piezoelectric actuator in accordance with an embodiment of the invention.

### DESCRIPTION OF THE PREFERRED EMBODIMENT

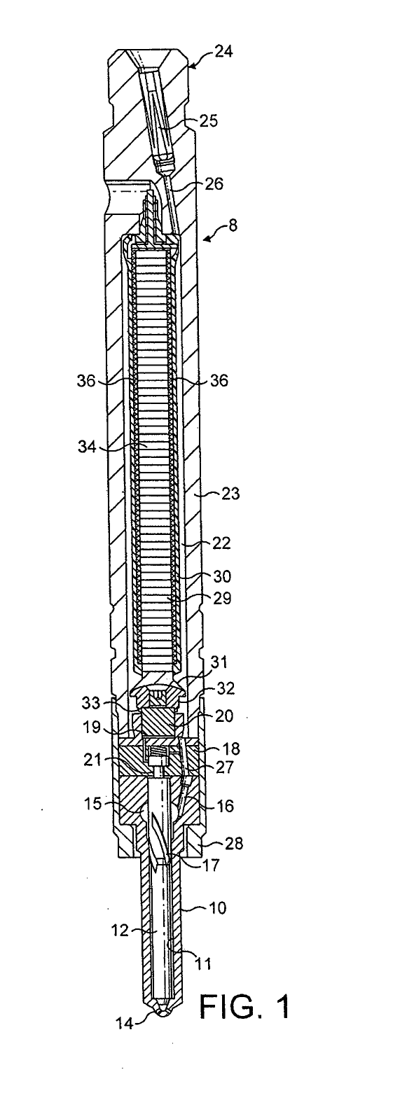

A known piezoelectric actuated fuel injector 8 is depicted in FIG. 1. The fuel injector 8 generally includes an injector body 10 having an axially extending fuel passage 11, an injector valve 12 axially moveable within the fuel passage 11, a piezoelectric element 29 for actuating the injector valve 12, and a hydraulic assembly 18 for interfacing between the piezoelectric element 29 and the injector valve 12, where the longitudinal expansion of the piezoelectric element 29 axially separates the injector valve 12 from its seating, thereby allowing fuel flow from the fuel injector.

The piezoelectric actuator 29 is located within the accumulator 22 and comprises a stack of piezoelectric discs 34 with external electrodes 36. The piezoelectric element of the actuator 29 is overmoulded with a thermoplastic polymer coating 30 to restrict the ingress of fuel into the joints between the individual elements forming the actuator 29.

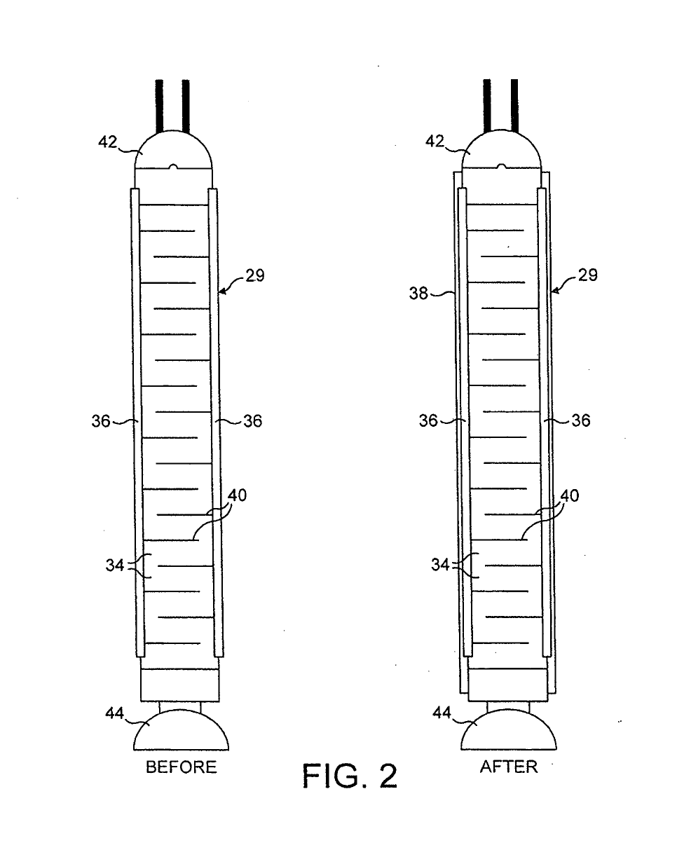

As shown schematically in the before and after diagrams of FIG. 2, the electrodes 36 of the piezoelectric actuator 29 may be protected by a passivation material 38.

In particular, the piezoelectric actuator 29 comprises a multilayer piezoelectric element made up of piezoelectric discs 34 interdigitated with electrodes 40. External electrodes 36 provide the electrical contact between electrodes 40 and the top end-piece 42. Top end-piece 42 at the upper end of the stack incorporates the combined electrical connection and seal to the injector body (not shown) and at the opposite end is lower end seal 44 which couples to the motion amplifier (not shown). A passivation material 38 such as silicone rubber is then applied to cover both the exposed faces of electrodes 40 and the external electrodes 36.

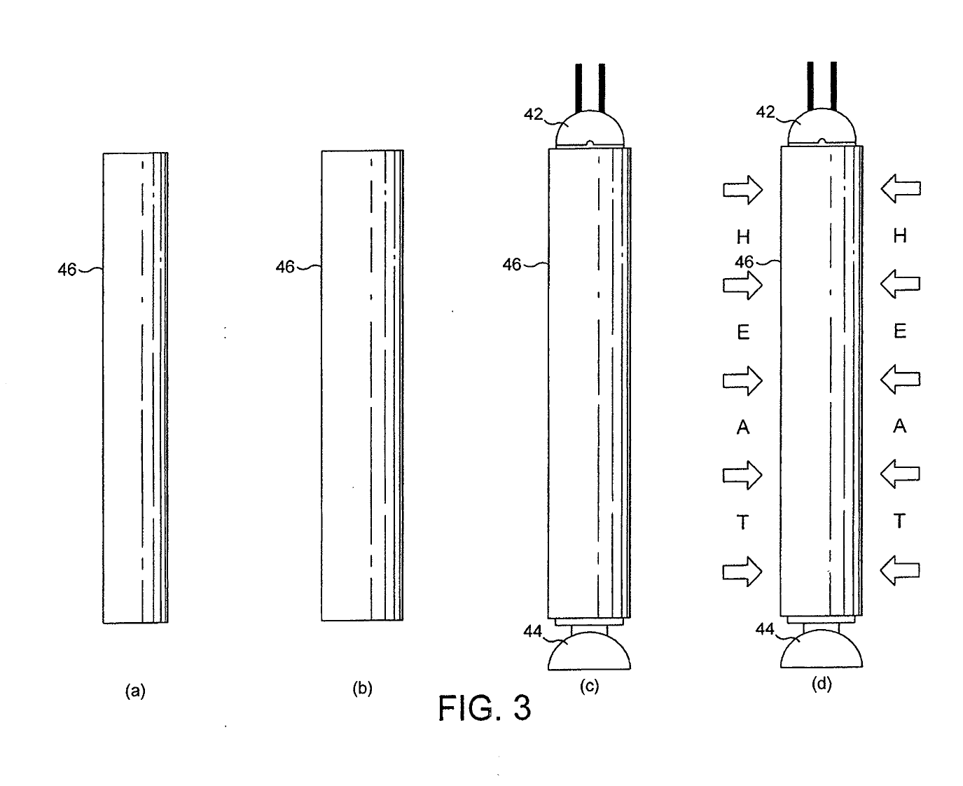

In the prior art, after passivation, the piezoelectric actuator 29 may then be subjected to further treatment, such as overmoulding with a polymer. However, none of the known polymer coatings has proved entirely reliable in terms of preventing ingress of fuel and/or water into the actuator. Hence, instead of overmoulding with a thermoplastic polymer coating 30 as shown in FIG. 1, the actuator 29 may be encapsulated in a shape memory alloy as shown schematically in FIG. 3.

Specifically, step (a) shows a shape memory alloy tube 46 made to a specified length and diameter appropriate to fit closely around the passivated piezoelectric stack of FIG. 2. Once the shape memory alloy tube 46 has been machined to the correct dimensions, it is then stretched over a mandrel (not shown) which has a larger external diameter than that of the internal diameter of the manufactured tube 46 as shown in step (b).

The stretched shape memory alloy tube 46 is then removed from the mandrel whereupon it is of sufficiently large diameter to be slipped over the passivated stack as shown in step (c). Once in position on the passivated stack, with the passivation layer being covered, heat is applied to the exterior of the stretched shape memory alloy tube 46 as shown in step (d). The heat should be sufficient to raise the temperature of the tube 46 to the alloy's transformation temperature, whereupon it returns to its original manufactured shape and consequently fits tightly around the passivated stack. In this way, it is possible to exclude any fuel and/or water from penetrating through to the passivation layer when the actuator is in situ surrounded by pressurized fuel.

While the above description constitutes the preferred embodiment of the invention, it will be appreciated that the invention is susceptible to modification, variation and change without departing from the scope of the invention as defined by the accompanying claims.

1. A method of protecting an electrical device against permeation by injurious fluids, such as fuel (diesel/gasoline) and water, said method including encapsulating the electrical device with a shape-memory, metallic material.

2. A method according to claim 1, comprising forming the shape-memory metallic material as a tube having an internal diameter substantially similar to the external diameter of the electrical device prior to encapsulation.

3. A method according to claim 2, comprising machining the shape-memory, metallic material to the required dimensions.

4. A method according to claim 3, comprising machining the shape-memory, metallic material to a wall thickness of about 1 mm or less.

5. A method according to claim 4, comprising machining the shape-memory, metallic material to a wall thickness of about 200 to 500 microns.

6. A method according to claim 2, comprising deforming the shape-memory, metallic tube below its transformation temperature to an internal diameter greater than the electrical device, placing the deformed tube over the electrical device, and then heating the tube to above its transformation temperature such that the tube reverts to its original shape and encapsulates the electrical device.

7. A method according to claim 6, comprising stretching the tube around a mandrel.

8. A method according to claim 6, comprising stretching the tube by about 4% before being placed over the electrical device.

9. A method according to claim 1, comprising encapsulating a piezoelectric actuator for use in a fuel injection system.

10. A method according to claim 9, wherein the piezoelectric actuator is passivated, and the method comprises encapsulating the actuator by the shape-memory, metallic material so as to isolate the passivation.

11. A method according to claim 10, comprising manufacturing the shape-memory, metallic material to a shape that exerts substantially no stress on the passivation after encapsulation.

12. A method according to claim 11, comprising manufacturing the shape-memory, metallic material to provide a gap of about 0.5 mm or less between the shape-memory, metallic material and the passivation.

13. A method according to claim 9, wherein the piezoelectric actuator is connected to end pieces for providing an electrical connection and/or a seal to the fuel injector body, and the method comprises sealing the shape-memory, metallic material to the end pieces.

14. A method according to claim 13, comprising applying a sealant between the end pieces and the shape-memory, metallic material.

15. The method of claim 1, comprising using a shape-memory, metallic material to encapsulate an electrical device so as to protect against permeation by injurious fluids such as fuel (diesel/gasoline) and water.

16. The method of claim 15, wherein the shape-memory, metallic material is a shape-memory, metallic alloy.

17. The method of claim 16, wherein the shape-memory, metallic material is a nickel titanium alloy such as NITINOL™.

18. The method of claim 15, wherein the electrical device is a piezoelectric actuator.

19. The method of claim 18, wherein the piezoelectric actuator is a passivated piezoelectric actuator.

20. An electrical device such as a piezoelectric actuator encapsulated by a shape memory metallic material to protect against permeation by injurious fluids such as fuel (diesel/gasoline) and water.

21. A fuel injector incorporating an electrical device according to claim 20.

22. A fuel injector according to claim 21, wherein the electrical device is a piezoelectric actuator and is encapsulated using a method according to any one of claims 2 to 14.
